(19) United States
(12) Patent Application Publication
(10) Pub. No.: US 2010/0079553 A1
(43) Pub. Date: Apr. 1, 2010

(54) LIQUID EJECTION HEAD DRIVE CIRCUIT, LIQUID EJECTION APPARATUS, AND METHOD OF PROTECTING LIQUID EJECTION HEAD DRIVE CIRCUIT

(76) Inventor: Yoshinori Katoh, Kanagawa-ken (JP)

Correspondence Address: BIRCH STEWART KOLASCH & BIRCH, PO BOX 747, FALLS CHURCH, VA, 22040-0747, US

(21) Appl. No.: 12/567,134

(22) Filed: Sep. 25, 2009

(30) Foreign Application Priority Data
Sep. 26, 2008 (JP) 2008-248489

(51) Int. Cl. B41J 2/045; H01L 41/09

(52) U.S. Cl. 347/68; 310/317

(57) ABSTRACT

The liquid ejection head drive circuit includes: a drive voltage application device which applies drive voltage between a drive electrode and a common electrode of a piezoelectric element arranged in a liquid ejection head; a detection device which detects a current flowing in a common line which is electrically connected to the common electrode; an abnormal insulation determination device which determines a status of abnormal insulation of the piezoelectric element according to a detection result of the detection device; and a current limitation device which limits the current flowing in the common line within a prescribed range where the abnormal insulation determination device is enabled to determine the status of abnormal insulation, when the current flowing in the common line exceeds a reference value which is determined so that at least one of the detection device and the drive voltage application device is prevented from being overloaded.

### BACKGROUND OF THE INVENTION

1. Field of the Invention

The present invention relates to a liquid ejection head drive circuit, a liquid ejection apparatus, and a method of protecting such a liquid ejection head drive circuit, and more particularly to technology for protecting a drive circuit of a liquid ejection head including piezoelectric elements.

2. Description of the Related Art

Generally, an inkjet recording apparatus is broadly used as a general-purpose image formation device for forming color images. An inkjet recording apparatus includes, for example, inkjet heads corresponding to the respective colors of K (black), C (cyan), M (magenta), and Y (yellow), and is configured to eject color ink from the respective heads provided for the colors and forming the intended color image on a recording medium.

In the inkjet head, ejection force generating elements such as piezoelectric actuators are provided respectively to a plurality of nozzles, and, when a prescribed drive voltage is applied to the ejection force generating element, a prescribed amount of ink is ejected from the corresponding nozzle at a prescribed timing.

The piezoelectric actuator used in the inkjet head has a structure where a piezoelectric body formed from a piezoelectric material is sandwiched by two electrodes, and is electrically equivalent to a capacitor. Moreover, a prescribed insulation performance is yielded between the electrodes in a piezoelectric actuator of a normal status, and its resistance value is generally several megaohms (MΩ) to several hundred MΩ. Nevertheless, there are cases where the resistance value between the electrodes drops to several hundred kiloohms (kΩ) or less due to some kind of abnormality. As the reason for this kind of deterioration in insulation performance, the following cases (1) to (3) can be considered:

(1) the short circuit of electrodes due to a manufacturing defect;
(2) even though the electrodes were initially normal, the metal material that is used in the electrode migrates into the piezoelectric body due to a long-term operation, which eventually results in a short circuit; and
(3) the ink exudes to the live parts as a result of the insulation structure between the ink and the live parts being damaged, and current flowing between the electrodes through the ink.

The above-described case (3) is unique to an inkjet head. Some kind of measure must be taken against abnormal insulation.

Japanese Patent Application Publication No. 2004-058633 discloses an ink leakage detection method in which a pair of electrodes for ink leakage detection is arranged to surround a plurality of piezoelectric elements, and configured to issue a prescribed warning when it is detected that the potential difference between both the electrodes has exceeded a prescribed threshold value.

Meanwhile, as a method of determining the status of deterioration in the insulation performance of the piezoelectric actuator, known is a method of monitoring the resistance value between the electrodes of the piezoelectric actuator, and determining the pass/fail of the insulation performance of the piezoelectric actuator based on the monitor result.

With the foregoing method, a resistor (monitor resistor) is connected serially to the inkjet head, and the voltage generated at both ends of the monitor resistor when DC voltage is applied to the inkjet head is checked.

FIG. 12 shows a configuration example using such a monitor resistor. The inkjet head 200 shown in FIG. 12 includes: a plurality of piezoelectric elements 202, which function as ejection force generating elements; and switch elements 204 for switching the ON/OFF of the piezoelectric elements 202. A common drive voltage is applied to the respective piezoelectric elements 202 through a drive voltage line 206 and the switch elements 204 according to the “ON” of the switch elements 204. The electrodes, which are located on the opposite side of the electrodes to which the switch elements 204 of the piezoelectric elements 202 is connected, are connected to a common voltage line 208.

As shown in FIG. 12, the piezoelectric element 202 has a structure where a capacitor component 202A and a resistance component 202B are connected in parallel when represented with an electrical equivalent circuit, and the resistance component B is the insulation resistance of the piezoelectric elements 202.

The inkjet head 200 is connected to a drive circuit board 242 to which a drive circuit 240 for generating the drive voltage is mounted, through a flexible flat cable 223 on which a drive voltage pattern 220 and a common voltage pattern 222 to become the transmission paths of the drive voltage are formed.

The drive circuit 240 generating the drive voltage includes: a D/A converter 246 for converting a digital waveform data sequence 244 into analog signals; an amplifier 250 for amplifying the analog signals and outputting the drive voltage; a common line 252, which is electrically connected to the common voltage line 208 of the inkjet head 200 through the common voltage pattern 222 of the flexible flat cable 223; a monitor resistor 254, which is connected to the common line 252; and a capacitor (decoupling capacitor) 260, which is connected in parallel to the monitor resistor 254.

Moreover, although not shown in the drawing, a connector (receptacle) is arranged on an end of the drive circuit board 242. The connector has a pin (electrode) which is connected to the drive voltage line and a pin (electrode) which is connected to the common line, and is in a shape of engaging with the connector (plug) to be connected to the end of the flexible flat cable 223.

Since a potential that is proportionate to the common current I_{R} flowing in the common line 252 appears in the monitor resistor 254, the increase or decrease of the common current I_{R} can be determined by monitoring the monitor voltage that appears at both ends of the monitor resistor 254. With the configuration shown in FIG. 12, the monitor voltage is amplified with the amplifier 256, and the status of abnormal insulation of the piezoelectric element 202 is thereafter determined using a pass/fail determination unit 258.

For example, if the insulation resistance (resistance value of the resistance component 202B) of the piezoelectric element 202 decreases due to deterioration with age or the like, since the common current I_{R} (path of the common current I_{R} is illustrated with directional lines) flowing in the drive circuit 240, the insulation resistance (resistance component 202B) and the monitor resistor 254 increases, the monitor voltage appearing at both ends of the monitor resistor 254 also increases. Hence, the value of the insulation resistance of the piezoelectric element 202 can be determined from the voltage between both ends of the monitor resistor 254 (potential of point B in FIG. 12), the drive voltage (DC voltage, potential of point A in FIG. 12), and the resistance value of the monitor resistor 254.

Meanwhile, when ejecting ink from the inkjet head 200, a time-variable drive voltage (including a high-frequency AC component) is applied to the piezoelectric elements 202. More specifically, each time the voltage changes, a charge-discharge current flows to the capacitor component 202A of the piezoelectric element 202. Since the potential of point B varies when the charge-discharge current flows to the monitor resistor 254, the voltage (“potential of point A”—“potential of point B”) to be applied between both electrodes of the piezoelectric actuator also varies.

With the configuration illustrated in FIG. 12, the capacitor 260 is connected in parallel to the monitor resistor 254 to lower the impedance against the time-variable current, and suppress the variance in the potential (monitor voltage) of point B.

In the ink leakage detection method described in Japanese Patent Application Publication No. 2004-058633, since it is necessary to provide the electrodes for ink leakage detection and slits for achieving high sensitivity, the miniaturization of the inkjet head is inhibited. Moreover, a circuit for applying voltage to the electrodes for the ink leakage detection is indispensible, and a signal line for voltage application and detection is also required. Consequently, the enlargement of the drive circuit, the interface, and the inkjet head is inevitable.

On the other hand, in the method described with reference to FIG. 12, it is not necessary to provide a special electrode to the head, and it is also not necessary to provide a circuit for applying voltage on the drive circuit side for the ink leakage detection, and a dedicated signal line.

Meanwhile, if the resistance value of the monitor resistor 254 is increased in the configuration illustrated in FIG. 12, it could be said that the detection sensitivity increases since a relatively large detection voltage can be obtained. Nevertheless, since the voltage to be applied to the piezoelectric elements 202 decreases for the amount of the foregoing voltage increase, there is a problem in that the ejection efficiency of the inkjet head deteriorates. Hence, since this impairs the primary ink ejection function of the inkjet head, the increase in the resistance value of the monitor resistor 254 is not necessarily favorable.

On the other hand, if the resistance value of the monitor resistor 254 is reduced, the current flowing in the monitor resistor 254 (the common current I_{R} in FIG. 12) increases when the insulation resistance 202B of the piezoelectric element 202 decreases. When the common current I_{R} increases, the power consumed by the monitor resistor 254 and the drive circuit 240 increases, and the power transistor (not shown) of the output stage of the monitor resistor 254 and the drive circuit 240 may become destroyed due to heat. This phenomenon could also occur even if the deterioration in the insulation resistance 202B of the piezoelectric element 202 is within a normal range.

In general, the drive voltage of the piezoelectric actuator that is used in the inkjet head 200 is of a large value of approximately 20 V to 30 V, and the increase in the monitor resistance and current flowing in the drive circuit 240 (i.e., heat generation) due to the deterioration in the insulation resistance 202B is anticipated to be significant.

### SUMMARY OF THE INVENTION

The present invention has been contrived in view of the above-described circumstances, an object thereof being to provide a liquid ejection head drive circuit and a method of protecting such liquid ejection head drive circuit capable of avoiding the malfunction of the drive circuit and the like caused by the deterioration in the insulation resistance value and continuing the determination of abnormal insulation upon determining the abnormal insulation of piezoelectric elements arranged in the liquid ejection head.

In order to attain the aforementioned object, the present invention is directed to a liquid ejection head drive circuit, comprising: a drive voltage application device which applies drive voltage between a drive electrode and a common electrode of a piezoelectric element arranged in a liquid ejection head; a detection device which detects a current flowing in a common line which is electrically connected to the common electrode; an abnormal insulation determination device which determines a status of abnormal insulation of the piezoelectric element according to a detection result of the detection device; and a current limitation device which limits the current flowing in the common line within a prescribed range where the abnormal insulation determination device is enabled to determine the status of abnormal insulation, when the current flowing in the common line exceeds a reference value which is determined so that at least one of the detection device and the drive voltage application device is prevented from being overloaded.

According to the present invention, in the drive circuit for supplying the prescribed drive voltage to the liquid ejection head including the piezoelectric element, since the common current is limited when such common current exceeds the prescribed value upon determining the status of abnormal insulation of the piezoelectric elements according to the common current flowing in the common line that is electrically connected to the common electrode of the piezoelectric element, it is possible to avoid damages to the detection device or the elements configuring the drive circuit due to an overload. Moreover, since the common current is limited within a range where the status of abnormal insulation of the piezoelectric element can be determined, the status of abnormal insulation of the piezoelectric element can be determined even in a state where the common current is limited.

### BRIEF DESCRIPTION OF THE DRAWINGS

FIG. 1 is a general schematic drawing of an inkjet recording apparatus according to an embodiment of the present invention;

FIG. 2 is a plan view of principal components around a print unit of the inkjet recording apparatus in FIG. 1;

FIGS. 3A to 3C are planar perspective views showing structural examples of a head;

FIG. 4 is a cross sectional view along line 4-4 in FIGS. 3A and 3B;

FIG. 5 is an enlarged view showing the nozzle arrangement of the head shown in FIGS. 3A to 3C;

FIG. 6 is a schematic drawing showing the configuration of an ink supply system of the inkjet recording apparatus in FIG. 1;

FIG. 7 is a schematic drawing showing the configuration of a control system of the inkjet recording apparatus in FIG. 1;

FIG. 8 is a block diagram showing the configuration of a drive circuit included in the head driver shown in FIG. 7;

FIG. 9 is a block diagram showing the configuration example of a common current controller shown in FIG. 8;

FIG. 10 is a block diagram showing another configuration example of the common current controller shown in FIG. 8;

FIG. 11 is a block diagram showing a configuration example of the common current controller in a case of using a minus voltage in the drive circuit shown in FIG. 10; and

FIG. 12 is a diagram explaining a drive circuit of a liquid ejection head in the related art.

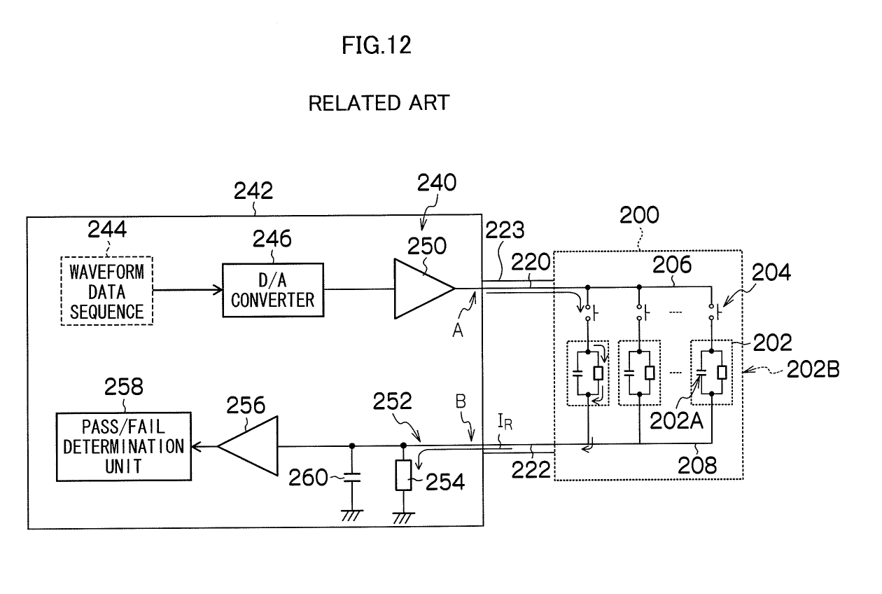

### DETAILED DESCRIPTION OF THE PREFERRED EMBODIMENTS

### General Composition of Inkjet Recording Apparatus

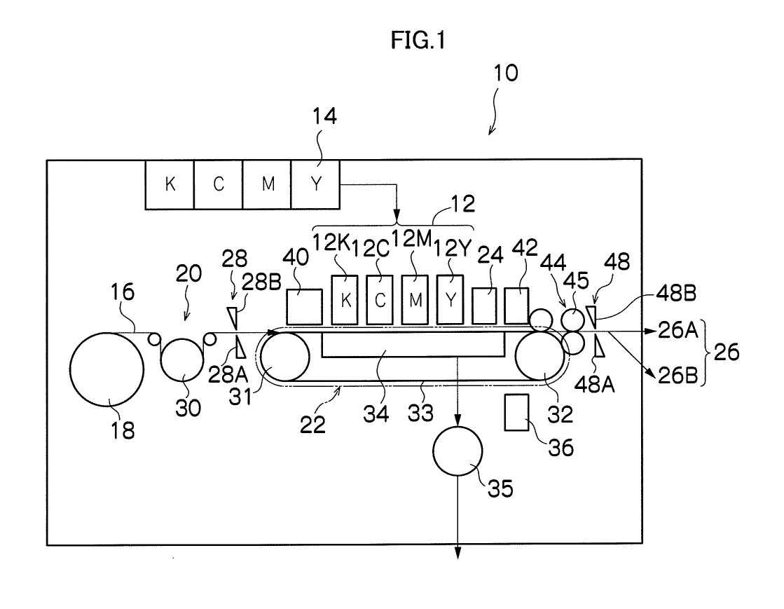

FIG. 1 is a diagram of the general composition of an inkjet recording apparatus according to an embodiment of the present invention. As shown in FIG. 1, the inkjet recording apparatus 10 includes: a print unit 12 having a plurality of inkjet heads (hereafter, called “heads”) 12K, 12C, 12M, and 12Y provided for colored inks of black (K), cyan (C), magenta (M), and yellow (Y), respectively; an ink storing and loading unit 14 for storing the inks of K, C, M and Y to be supplied to the heads 12K, 12C, 12M, and 12Y; a paper supply unit 18 for supplying recording paper 16, which is a recording medium; a decurling unit 20 removing curl in the recording paper 16; a suction belt conveyance unit 22 disposed facing the ink ejection faces (nozzle forming surfaces) of the heads 12K, 12C, 12M, and 12Y, for conveying the recording paper 16 while keeping the recording paper 16 flat; and a paper output unit 26 for outputting image-printed recording paper (printed matter) to the exterior.

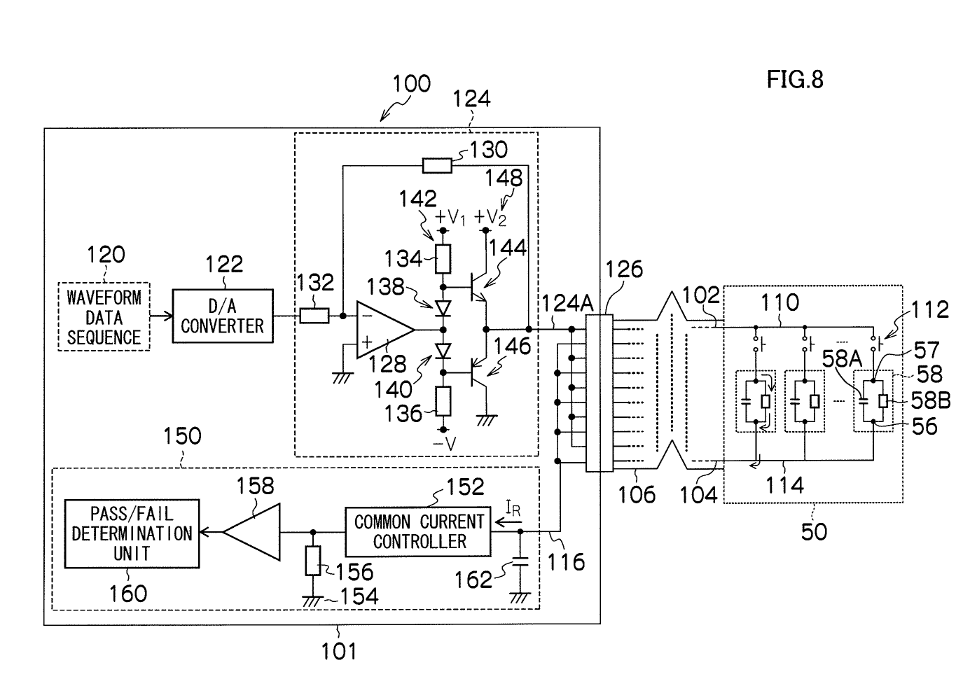

Although not shown in FIG. 1, drive circuit boards 101 (shown in FIG. 8) of the respective heads 12K, 12C, 12M, 12Y are arranged in an erect manner to the top faces (faces that are opposite to the faces that face the recording paper 16) of the respective heads 12K, 12C, 12M, 12Y included in the print unit 12.

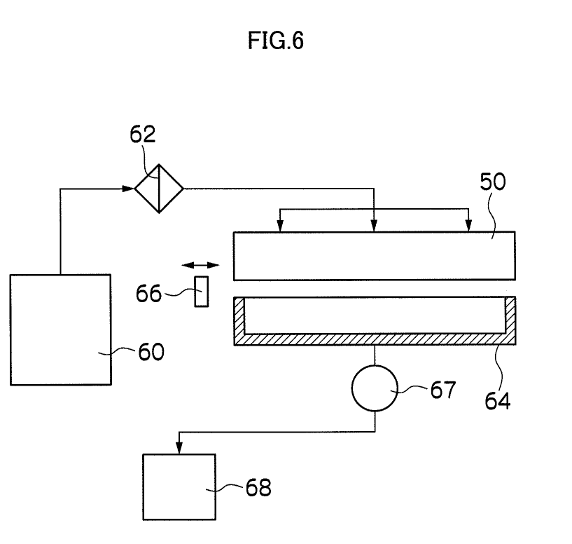

The ink storing and loading unit 14 has ink supply tanks 60 (not shown in FIG. 1, and shown in FIG. 6) for storing the inks of K, C, M and Y to be supplied to the heads 12K, 12C, 12M, and 12Y, and the ink supply tanks are respectively connected to the heads 12K, 12C, 12M, and 12Y by means of prescribed ink flow channels.

The ink storing and loading unit 14 has a warning device (for example, a display device or an alarm sound generator) for warning when the remaining amount of any ink is low, and has a mechanism for preventing loading errors among the colors. The details of the ink supply system including the ink storing and loading unit 14 shown in FIG. 1 are described later.

In FIG. 1, a magazine for rolled paper (continuous paper) is shown as an example of the paper supply unit 18; however, more magazines with paper differences such as paper width and quality may be jointly provided. Moreover, papers may be supplied with cassettes that contain cut papers loaded in layers and that are used jointly or in lieu of the magazine for rolled paper.

In the case of a configuration in which a plurality of types of recording paper can be used, it is preferable that an information recording medium such as a bar code and a wireless tag containing information about the type of paper is attached to the magazine, and by reading the information contained in the information recording medium with a predetermined reading device, the type of recording medium to be used (type of medium) is automatically determined, and ink droplet ejection is controlled so that the ink droplets are ejected in an appropriate manner in accordance with the type of medium.

The recording paper 16 delivered from the paper supply unit 18 retains curl due to having been loaded in the magazine. In order to remove the curl, heat is applied to the recording paper 16 in the decurling unit 20 by a heating drum 30 in the direction opposite from the curl direction in the magazine. The heating temperature at this time is preferably controlled so that the recording paper 16 has a curl in which the surface on which the print is to be made is slightly round outward.

In the case of the configuration in which roll paper is used, a cutter (first cutter) 28 is provided as shown in FIG. 1, and the continuous paper is cut into a desired size by the cutter 28. The cutter 28 has a stationary blade 28A, whose length is not less than the width of the conveyor pathway of the recording paper 16, and a round blade 28B, which moves along the stationary blade 28A. The stationary blade 28A is disposed on the reverse side of the printed surface of the recording paper 16, and the round blade 28B is disposed on the printed surface side across the conveyor pathway. When cut papers are used, the cutter 28 is not required.

The decurled and cut recording paper 16 is delivered to the suction belt conveyance unit 22. The suction belt conveyance unit 22 has a configuration in which an endless belt 33 is set around rollers 31 and 32 so that the portion of the endless belt 33 facing at least the nozzle faces of the heads 12K, 12C, 12M, and 12Y (the ink ejection faces on which the nozzle orifices are formed) forms a horizontal plane (flat plane).

The belt 33 has a width that is greater than the width of the recording paper 16, and a plurality of suction apertures (not shown) are formed on the belt surface. A suction chamber 34 is disposed in a position facing the nozzle faces of the heads 12K, 12C, 12M, and 12Y on the interior side of the belt 33, which is set around the rollers 31 and 32, as shown in FIG. 1. The suction chamber 34 provides suction with a fan 35 to generate a negative pressure, and the recording paper 16 is held on the belt 33 by suction.

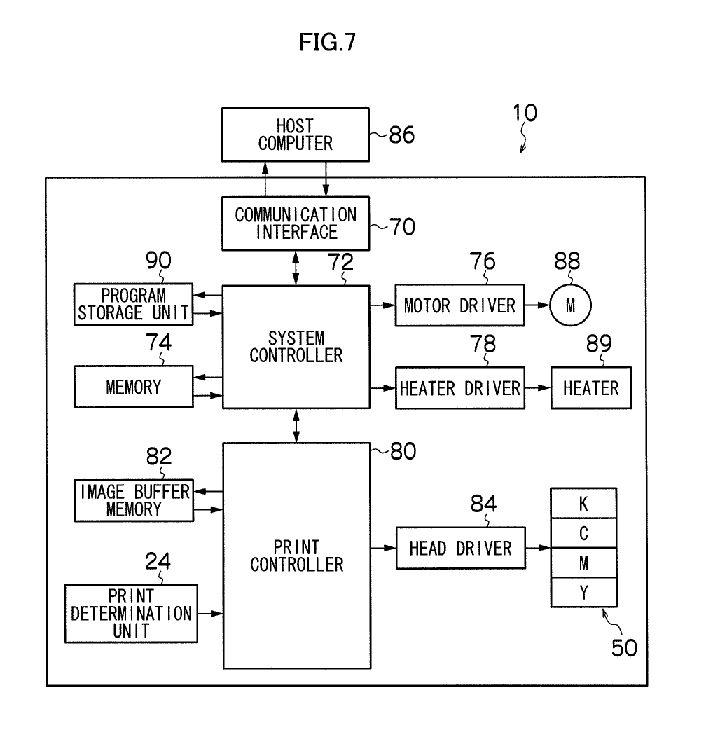

The belt 33 is driven in the clockwise direction in FIG. 1 by the motive force of a motor 88 (not shown in FIG. 1, and shown in FIG. 7) being transmitted to at least one of the rollers 31 and 32, which the belt 33 is set around, and the recording paper 16 held on the belt 33 is conveyed from left to right in FIG. 1.

Since the ink adheres to the belt 33 when a marginless print job or the like is performed, a belt-cleaning unit 36 is disposed in a predetermined position (a suitable position outside the printing area) on the exterior side of the belt 33. Although the details of the configuration of the belt-cleaning unit 36 are not shown, examples thereof include a configuration of nipping with a brush roller and a water absorbent roller, or an air blow configuration in which clean air is blown, or a combination of these. In the case of the configuration in which the belt 33 is nipped with the cleaning rollers, it is preferable to make the line velocity of the cleaning rollers different than that of the belt 33 to improve the cleaning effect.

The inkjet recording apparatus can have a roller nip conveyance mechanism, in place of the suction belt conveyance unit 22. However, there is a drawback in the roller nip conveyance mechanism that the print tends to be blurred when the printing area is conveyed by the roller nip action because the nip roller makes contact with the printed surface of the paper immediately after printing. Therefore, the suction belt conveyance in which nothing comes into contact with the image surface in the printing area is preferable.

A heating fan 40 is disposed on the upstream side of the print unit 12 in the conveyance pathway formed by the suction belt conveyance unit 22. The heating fan 40 blows heated air onto the recording paper 16 to heat the recording paper 16 immediately before printing so that the ink deposited on the recording paper 16 dries more easily.

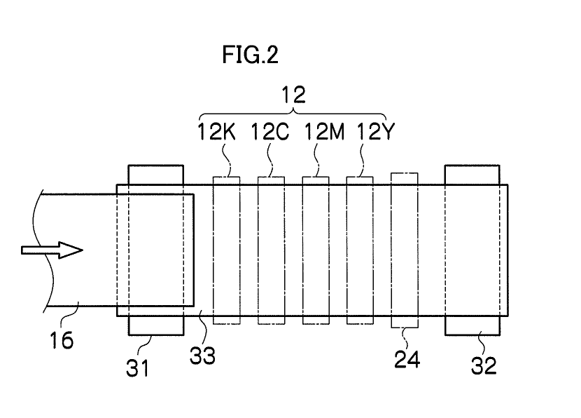

The heads 12K, 12C, 12M and 12Y of the print unit 12 are full line heads having a length corresponding to the maximum width of the recording paper 16 used with the inkjet recording apparatus 10, and having a plurality of nozzles for ejecting ink arranged on a nozzle face through a length exceeding at least one edge of the maximum-size recording medium (namely, the full width of the printable range) (see FIG. 2).

The heads 12K, 12C, 12M and 12Y are arranged in color order (black (K), cyan (C), magenta (M), yellow (Y)) from the upstream side in the feed direction of the recording paper 16, and the heads 12K, 12C, 12M and 12Y are fixed extending to the conveyance direction of the recording paper 16 (paper conveyance direction).

A color image can be formed on the recording paper 16 by ejecting and depositing inks of different colors from the heads 12K, 12C, 12M and 12Y, respectively, onto the recording paper 16 while the recording paper 16 is conveyed by the suction belt conveyance unit 22.

By adopting a configuration in which the full line heads 12K, 12C, 12M and 12Y having nozzle rows covering the full paper width are provided for the respective colors in this way, it is possible to record an image on the full surface of the recording paper 16 by performing just one operation of relatively moving the recording paper 16 and the print unit 12 in the paper conveyance direction, in other words, by means of a single sub-scanning action. Higher-speed printing is thereby made possible and productivity can be improved in comparison with a shuttle type head configuration in which a recording head reciprocates in the main scanning direction.

Although the configuration with the KCMY four standard colors is described in the present embodiment, combinations of the ink colors and the number of colors are not limited to those. Light inks, dark inks or special color inks can be added as required. For example, a configuration is possible in which inkjet heads for ejecting light-colored inks such as light cyan and light magenta are added. Furthermore, there are no particular restrictions of the sequence in which the heads of respective colors are arranged. In an inkjet recording apparatus based on a two-liquid system in which treatment liquid and ink are deposited on the recording paper 16, and the ink coloring material is caused to aggregate or become insoluble on the recording paper 16, thereby separating the ink solvent and the ink coloring material on the recording paper 16, it is possible to provide an inkjet head as a device for depositing the treatment liquid onto the recording paper 16.

It is possible that each of the heads 12K, 12C, 12M and 12Y has a construction in which a plurality of modules are connected in the widthwise direction of the recording paper. It is also possible that the heads 12K, 12C, 12M and 12Y are unitedly composed.

The print determination unit 24 has an image sensor for capturing an image of the ink-droplet deposition result of the print unit 12, and functions as a device to check for ejection abnormalities such as clogs of the nozzles in the print unit 12 from the ink-droplet deposition results evaluated by the image sensor.

The print determination unit 24 of the present embodiment is configured with at least a line sensor having rows of photoelectric transducing elements with a width that is greater than the ink-droplet ejection width (image recording width) of the heads 12K, 12C, 12M, and 12Y. This line sensor has a color separation line CCD sensor including a red (R) row of photoreceptor element composed of photoelectric transducing elements (pixels) arranged in a line provided with an R filter, a green (G) row of photoreceptor element with a G filter, and a blue (B) row of photoreceptor element with a B filter. Instead of a line sensor, it is possible to use an area sensor composed of photoelectric transducing elements which are arranged two-dimensionally.

The print determination unit 24 reads a test pattern image printed by the heads 12K, 12C, 12M, and 12Y for the respective colors, and the ejection of each head 12K, 12C, 12M, and 12Y is determined. The ejection determination includes the presence of the ejection, measurement of the dot size, and measurement of the dot deposition position.

A post-drying unit 42 is disposed following the print determination unit 24. The post-drying unit 42 is a device to dry the printed image surface, and includes a heating fan, for example. It is preferable to avoid contact with the printed surface until the printed ink dries, and a device that blows heated air onto the printed surface is preferable.

A heating/pressurizing unit 44 is disposed following the post-drying unit 42. The heating/pressurizing unit 44 is a device to control the glossiness of the image surface, and the image surface is pressed with a pressure roller 45 having a predetermined uneven surface shape while the image surface is heated, and the uneven shape is transferred to the image surface.

When the recording paper 16 is pressed by the heating/pressurizing unit 44, in cases in which printing is performed with dye-based ink on porous paper, blocking the pores of the paper by the application of pressure prevents the ink from coming contact with ozone and other substance that cause dye molecules to break down, and has the effect of increasing the durability of the print.

The printed matter generated in this manner is outputted from the paper output unit 26. The target print (i.e., the result of printing the target image) and the test print are preferably outputted separately. In the inkjet recording apparatus 10, a sorting device (not shown) is provided for switching the outputting pathways in order to sort the printed matter with the target print and the printed matter with the test print, and to send them to paper output units 26A and 26B, respectively. When the target print and the test print are simultaneously formed in parallel on the same large sheet of paper, the test print portion is cut and separated by a cutter (second cutter) 48. The cutter 48 is disposed directly in front of the paper output unit 26, and is used for cutting the test print portion from the target print portion when a test print has been performed in the blank portion of the target print. The structure of the cutter 48 is the same as the first cutter 28 described above, and has a stationary blade 48A and a round blade 48B.

Although not shown in FIG. 1, the paper output unit 26A for the target prints is provided with a sorter for collecting prints according to print orders.

### Structure of Head

Next, the structure of the head is described. The heads 12K, 12C, 12M and 12Y for the respective colored inks have the same structure, and a reference numeral 50 is hereinafter designated to any of the heads.

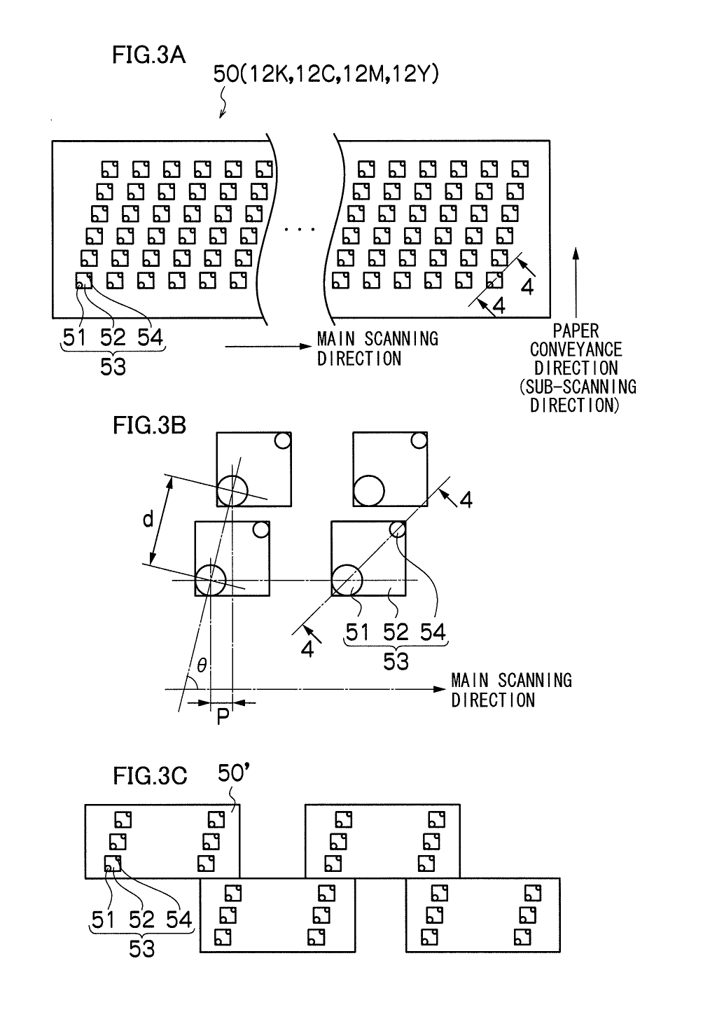

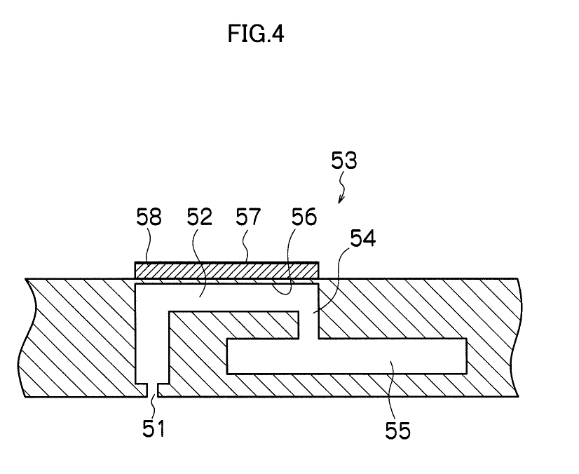

FIG. 3A is a perspective plan view showing an embodiment of the configuration of the head 50, FIG. 3B is an enlarged view of a portion thereof, FIG. 3C is a perspective plan view showing another example of the configuration of the head 50, and FIG. 4 is a cross-sectional view taken along the line 4-4 in FIGS. 3A and 3B, showing the inner structure of the head 50.

The nozzle pitch in the head 50 should be minimized in order to maximize the density of the dots printed on the surface of the recording paper 16. As shown in FIGS. 3A and 3B, the head 50 according to the present embodiment has a structure in which a plurality of ink chamber units 53, each comprising a nozzle 51 forming an ink droplet ejection hole, a pressure chamber 52 corresponding to the nozzle 51, and the like, are disposed two-dimensionally in the form of a staggered matrix, and hence the effective nozzle interval (the projected nozzle pitch) as projected in the lengthwise direction of the head 50 (the direction perpendicular to the paper conveyance direction) is reduced and high nozzle density is achieved.

The mode of forming one or more nozzle rows through a length corresponding to the entire width of the recording paper 16 in the main scanning direction substantially perpendicular to the conveyance direction of the recording paper 16 is not limited to the embodiment described above. For example, instead of the configuration in FIG. 3A, as shown in FIG. 3C, a line head having nozzle rows of a length corresponding to the entire width of the recording paper 16 can be formed by arranging and combining, in a staggered matrix, short head blocks 50′ having a plurality of nozzles 51 arrayed in a two-dimensional fashion. Furthermore, although not shown in the drawings, it is also possible to compose a line head by arranging short heads in one row.

The planar shape of the pressure chamber 52 provided for each nozzle 51 is substantially a square, and the nozzle 51 and supplied ink 54 are disposed in both corners on a diagonal line of the square. Each pressure chamber 52 is connected to a common channel 55 through the supply port 54. The common channel 55 is connected to an ink supply tank 60 (not shown in FIG. 4, and shown in FIG. 6), which is a base tank that supplies ink, and the ink supplied from the ink supply tank is delivered through the common flow channel 55 in FIG. 4 to the pressure chambers 52.

A piezoelectric element 58 provided with an individual electrode 57 is bonded to a diaphragm 56, which forms the upper face of the pressure chamber 52 and also serves as a common electrode, and the piezoelectric element 58 is deformed when a drive voltage is supplied to the individual electrode (drive electrode) 57, thereby causing the ink to be ejected from the nozzle 51. When ink is ejected, new ink is supplied to the pressure chamber 52 from the common flow passage 55, via the supply port 54.

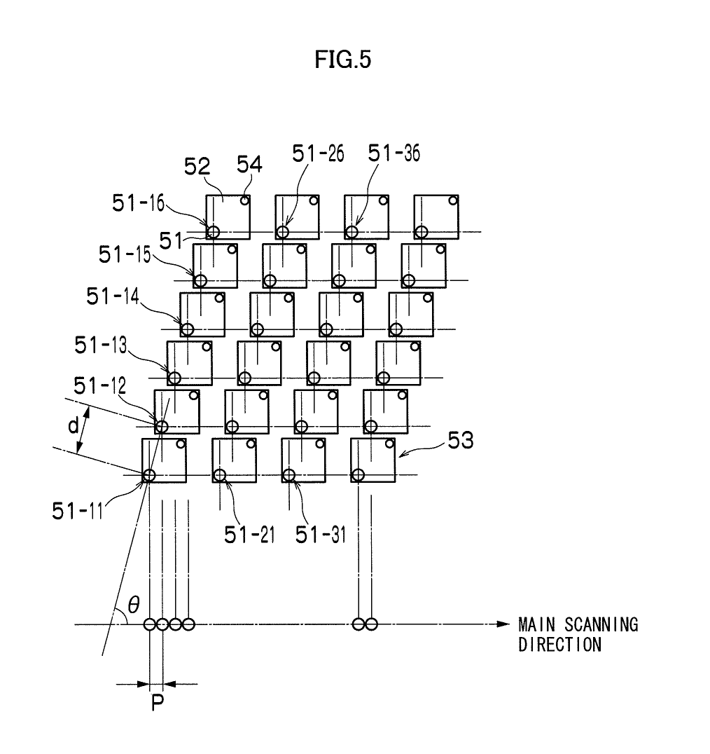

As shown in FIG. 5, the high-density nozzle head according to the present embodiment is achieved by arranging a plurality of ink chamber units 53 having the above-described structure in a lattice fashion based on a fixed arrangement pattern, in a row direction which coincides with the main scanning direction, and a column direction which is inclined at a fixed angle of θ with respect to the main scanning direction, rather than being perpendicular to the main scanning direction.

More specifically, by adopting a structure in which the ink chamber units 53 are arranged at a uniform pitch d in line with a direction forming an angle of θ with respect to the main scanning direction, the pitch P of the nozzles projected so as to align in the main scanning direction is d×cos θ, and hence the nozzles 51 can be regarded to be equivalent to those arranged linearly at a fixed pitch P along the main scanning direction. Such configuration results in a nozzle structure in which the nozzle row projected in the main scanning direction has a high nozzle density of up to 2,400 nozzles per inch.

In a full-line head comprising rows of nozzles that have a length corresponding to the entire width of the image recordable width, the “main scanning” is defined as printing one line (a line formed of a row of dots, or a line formed of a plurality of rows of dots) in the width direction of the recording paper (the direction perpendicular to the conveyance direction of the recording paper) by driving the nozzles in one of the following ways: (1) simultaneously driving all the nozzles; (2) sequentially driving the nozzles from one side toward the other; and (3) dividing the nozzles into blocks and sequentially driving the nozzles from one side toward the other in each of the blocks.

In particular, when the nozzles 51 arranged in a matrix such as that shown in FIGS. 3A and 3B are driven, the main scanning according to the above-described (3) is preferred. More specifically, the nozzles 51-11, 51-12, 51-13, 51-14, 51-15 and 51-16 are treated as a block (additionally; the nozzles 51-21, 51-22, . . . , 51-26 are treated as another block; the nozzles 51-31, 51-32, . . . , 51-36 are treated as another block; . . . ); and one line is printed in the widthwise direction of the recording paper 16 by sequentially driving the nozzles 51-11, 51-12, . . . , 51-16 in accordance with the conveyance velocity of the recording paper 16.

On the other hand, “sub-scanning” is defined as to repeatedly perform printing of one line (a line formed of a row of dots, or a line formed of a plurality of rows of dots) formed by the main scanning, while moving the full-line head and the recording paper 16 relatively to each other.

The main scanning direction is the direction along the one line (or the lengthwise direction of the band region) recorded by the above-described main scanning, and the sub-scanning direction is the direction along the above-describe sub-scanning is performed. That is, in the present embodiment, the conveyance direction of the recording paper is the sub-scanning direction, and the widthwise direction of the recording paper 16 perpendicular to the sub-scanning direction is the main scanning direction. When implementing the present invention, the arrangement structure of the nozzles is not limited to the embodiment shown in the drawings, and it is also possible to apply various other types of nozzle arrangements, such as an arrangement structure having one nozzle row in the sub-scanning direction.

### Configuration of Ink Supply System

FIG. 6 is a schematic drawing showing the configuration of the ink supply system in the inkjet recording apparatus 10. The ink supply tank 60 is a base tank that supplies the ink to the head 50 and is included in the ink storing and loading unit 14 described with reference to FIG. 1. The aspects of the ink supply tank 60 include a refillable type and a cartridge type: when the remaining amount of ink is low, the ink tank 60 of the refillable type is filled with ink through a filling port (not shown) and the ink tank 60 of the cartridge type is replaced with a new one. In order to change the ink type in accordance with the intended application, the cartridge type is suitable, and it is preferable to represent the ink type information with a bar code or the like on the cartridge, and to perform ejection control in accordance with the ink type.

A filter 62 for removing foreign matters and bubbles is disposed between the ink supply tank 60 and the head 50 as shown in FIG. 6. The filter mesh size in the filter 62 is preferably equivalent to or less than the diameter of the nozzle and commonly about 20 μm.

Although not shown in FIG. 6, it is preferable to provide a sub-tank integrally to the print head 50 or nearby the head 50. The sub-tank has a damper function for preventing variation in the internal pressure of the head and a function for improving refilling of the print head.

The inkjet recording apparatus 10 is also provided with a cap 64 as a device to prevent the nozzles 51 from drying out or to prevent an increase in the ink viscosity in the vicinity of the nozzles 51, and a cleaning blade 66 as a device to clean the nozzle face.

A maintenance unit including the cap 64 and the cleaning blade 66 can be relatively moved with respect to the head 50 by a movement mechanism (not shown), and is moved from a predetermined holding position to a maintenance position below the head 50 as required.

The cap 64 is displaced up and down relatively with respect to the head 50 by an elevator mechanism (not shown). When the power of the inkjet recording apparatus 10 is turned OFF or when in a print standby state, the cap 64 is raised to a predetermined elevated position so as to come into close contact with the head 50, and the nozzle face is thereby covered with the cap 64.

During printing or standby, if the use frequency of a particular nozzle 51 is low, and if a state of not ejecting ink continues for a prescribed time period or more, then the solvent of the ink in the vicinity of the nozzle evaporates and the viscosity of the ink increases. In a situation of this kind, it will become impossible to eject ink from the nozzle 51, even if the piezoelectric element 58 is operated.

Therefore, before a situation of this kind develops (namely, while the ink is within a range of viscosity which allows it to be ejected by operation of the piezoelectric element 58), the piezoelectric element 58 is operated, and a preliminary ejection (“purge”, “blank ejection”, “liquid ejection” or “dummy ejection”) is carried out toward the cap 64 (ink receptacle), in order to expel the degraded ink (namely, the ink in the vicinity of the nozzle which has increased viscosity).

Furthermore, if bubbles enter into the ink inside the head 50 (inside the pressure chamber 52), then even if the piezoelectric element 58 is operated, it will not be possible to eject ink from the nozzle. In a case of this kind, the cap 64 is placed on the head 50, the ink (ink containing bubbles) inside the pressure chamber 52 is removed by suction, by means of a suction pump 67, and the ink removed by suction is then supplied to a recovery tank 68.

This suction operation is also carried out in order to remove degraded ink having increased viscosity (hardened ink), when ink is loaded into the head for the first time, and when the head starts to be used after having been out of use for a long period of time. Since the suction operation is carried out with respect to all of the ink inside the pressure chamber 52, the ink consumption is considerably large. Therefore, desirably, preliminary ejection is carried out when the increase in the viscosity of the ink is still minor.

The cleaning blade 66 is composed of rubber or another elastic member, and can slide on the ink ejection surface (surface of the nozzle plate) of the head 50 by means of a blade movement mechanism (wiper) (not shown). When ink droplets or foreign matter has adhered to the nozzle plate, the surface of the nozzle plate is wiped and cleaned by sliding the cleaning blade 66 on the nozzle plate. When the soiling on the ink ejection surface is cleaned away by the blade mechanism, a preliminary ejection is also carried out in order to prevent the foreign matter from becoming mixed inside the nozzle 51 by the blade.

### Description of Control System

FIG. 7 is a principal block diagram showing the system configuration of the inkjet recording apparatus 10. The inkjet recording apparatus 10 includes a communication interface 70, a system controller 72, a memory 74, a motor driver 76, a heater driver 78, a print controller 80, an image buffer memory 82, a head driver 84, and the like.

The communication interface 70 is an interface unit for receiving image data sent from a host computer 86. A serial interface such as USB (Universal Serial Bus), IEEE1394, Ethernet, wireless network, or a parallel interface such as a Centronics interface may be used as the communication interface 70. A buffer memory (not shown) may be mounted in this portion in order to increase the communication speed. The image data sent from the host computer 86 is received by the inkjet recording apparatus 10 through the communication interface 70, and is temporarily stored in the memory 74.

The memory 74 is a storage device for temporarily storing images inputted through the communication interface 70, and data is written and read to and from the memory 74 through the system controller 72. The memory 74 is not limited to a memory composed of semiconductor elements, and a hard disk drive or another magnetic medium may be used.

The system controller 72 is constituted by a central processing unit (CPU) and peripheral circuit thereof, and the like, and it functions as a control device for controlling the whole of the inkjet recording apparatus 10 in accordance with a prescribed program, as well as a calculation device for performing various calculations. More specifically, the system controller 72 controls the various sections, such as the communication interface 70, memory 74, motor driver 76, heater driver 78, and the like, as well as controlling communications with the host computer 86 and writing and reading to and from the image memory 74, and it also generates control signals for controlling the motor 88 and heater 89 of the conveyance system.

The program executed by the CPU of the system controller 72 and the various types of data which are required for control procedures are stored in the memory 74. The memory 74 may be a non-writeable storage device, or it may be a rewriteable storage device, such as an EEPROM. The memory 74 is used as a temporary storage region for the image data, and it is also used as a program development region and a calculation work region for the CPU.

The motor driver 76 drives the motor 88 in accordance with commands from the system controller 72. In FIG. 6, the motors (actuators) disposed in the respective sections of the apparatus are represented by the reference numeral 88. For example, the motor 88 shown in FIG. 7 includes the motor that drives the drum 31 (32) in FIG. 1, a motor of the movement mechanism that moves the cap 64 in FIG. 5, a motor of the movement mechanism that moves the cap 64 in FIG. 6, and the like.

The heater driver 78 is a driver which drives heaters 89, including a heater forming a heat source of the heating fan 40 shown in FIG. 1, a heater of the post drying unit 42, and the like, in accordance with instructions from the system controller 72.

The print controller 80 has a signal processing function for performing various tasks, compensations, and other types of processing for generating print control signals from the image data stored in the memory 74 in accordance with commands from the system controller 72 so as to supply the generated print data (dot data) to the head driver 84. Prescribed signal processing is carried out in the print controller 80, and the ejection amount and the ejection timing of the ink droplets from the respective print heads 50 are controlled via the head driver 84, on the basis of the print data. By this means, prescribed dot size and dot positions can be achieved.

The print controller 80 is provided with the image buffer memory 82; and image data, parameters, and other data are temporarily stored in the image buffer memory 82 when image data is processed in the print controller 80. Also possible is an aspect in which the print controller 80 and the system controller 72 are integrated to form a single processor.

The head driver 84 is configured by including a drive circuit (shown as reference numeral 100 in FIG. 8) for creating a drive voltage to be applied to the piezoelectric elements 58 of the head 50 in accordance with the image data provided from the print controller 80, and driving the piezoelectric elements 58 by applying such drive voltage to the piezoelectric elements 58. The head driver 84 shown in FIG. 7 may also include a feedback control system for maintaining the drive conditions of the head 50 in a constant manner.

The inkjet recording apparatus 10 of the present embodiment adopts the drive system of the piezoelectric element 58 for ejecting ink from the nozzles corresponding to the respective piezoelectric elements 58 by applying a drive voltage having a common drive waveform to the respective piezoelectric elements 58, and switching the ON/OFF of the switch element 128 (shown in FIG. 8) connected to the individual electrodes of the respective piezoelectric elements 58 according to the ejection timing of the respective piezoelectric elements 58.

The print determination unit 24 is a block that includes the line sensor as described above with reference to FIG. 1, reads the image printed on the recording paper 16, determines the print conditions (presence of the ejection, variation in the dot formation, and the like) by performing desired signal processing, or the like, and provides the determination results of the print conditions to the print controller 80.

According to requirements, the print controller 80 makes various corrections with respect to the head 50 or carries out the maintenance of the head 50 on the basis of information obtained from the print determination unit 24.

The image data to be printed is externally inputted through the communication interface 70, and is stored in the memory 74. In this stage, the RGB image data is stored in the memory 74.

The image data stored in the memory 74 is sent to the print controller 80 through the system controller 72, and is converted to the dot data for each ink color, in the print controller 80. In other words, the print controller 80 performs processing for converting the inputted RGB image data into dot data for the four colors, K, C, M and Y. The dot data generated by the print controller 80 is stored in the image buffer memory 82.

Various control programs are stored in a program storage section 90, and a control program is read out and executed in accordance with commands from the system controller 72. The program storage section 90 may use a semiconductor memory, such as a ROM, EEPROM, or a magnetic disk, or the like. An external interface may be provided, and a memory card or PC card may also be used. Naturally, a plurality of these storage media may also be provided. The program storage section 90 may also be combined with a storage device for storing operational parameters, and the like (not shown).

### Detailed Description of Drive Circuit of Head

The configuration and function of the drive circuit of the head 50 (i.e., the drive circuit of the piezoelectric elements (piezoelectric actuators) provided to the head 50) included in the head driver 84 shown in FIG. 7 are described in detail.

FIG. 8 shows a schematic configuration of the drive circuit 100 of the head 50. As shown in FIG. 8, the drive circuit 100 has a function of generating a drive voltage having electrical energy (voltage and current) for operating the piezoelectric elements 58 that generate ejection pressure upon ejecting ink from the head 50, and is mounted on a drive circuit board 101, which is connected to the head 50 through a flexible flat cable 106 with prescribed wiring patterns 102 and 104 formed therein.

The drive signal created with the drive circuit 100 is transmitted to the drive electrodes 57 of the piezoelectric elements 58 through the drive wiring pattern 102 of the flexible flat cable 106 and a drive voltage wiring 110 of the head 50. The common electrodes 56 of the piezoelectric elements 58 are electrically connected to a common line 116 of the drive circuit 100 through a common voltage wiring 114 of the head 50 and the common wiring pattern 104 of the flexible flat cable 106.

The drive circuit 100 shown in FIG. 8 includes a D/A converter 122 for converting the digital waveform data sequence 120 into analog signals, and an amplifier 124 for amplifying the analog signals of the waveform data sequence converted with the D/A converter 122. An output end 124A of the amplifier 124 is electrically connected to a pin (not shown) of the connector 126 mounted on the end of the drive circuit board 101.

The amplifier 124 includes: an amplifier 128, which amplifies the analog signals converted with the D/A converter 122; resistors 130 and 132, which configure the feedback circuit of the amplifier 128; a bias circuit 142, which includes resistors 134 and 136 and diodes 138 and 140, and operates based on the power source voltage of +V₁ and −V; and a conversion unit 148, which is constituted of transistors 144 and 146 forming a totem-pole connection, and converts the analog signals amplified with the amplifier 128 into a drive voltage. The configuration of the amplifier 124 illustrated in FIG. 8 is merely an example, and may be changed as needed.

The drive circuit 100 of the present embodiment is provided with an abnormal insulation determination unit 150 for determining the status of abnormal insulation of the piezoelectric elements 58, and a common current controller 152 for limiting the current (common current I_{R}) flowing in a monitor resistor 156 when the elements configuring the monitor resistor 156 and the drive circuit 100 become overloaded.

With the abnormal insulation determination unit 150, the monitor resistor 156 provided between the common line 116 and the ground 154 monitors the common current I_{R}, an amplification processing unit 158 performs amplification processing to the monitor voltage generated at both ends of the monitor resistor 156, and a pass/fail determination unit 160 determines the status of abnormal insulation in accordance with the monitor voltage produced by the amplification processing. Moreover, at the front side of the monitor resistor 156 (between the common electrode 56 of the piezoelectric element 58 and the monitor resistor 156), a capacitor 162 is provided between the common line 116 and the ground 154 for lowering the impedance of the common line 116 against the pulse current.

If the resistance value of the insulation resistance 58B deteriorates among the piezoelectric elements 58, the current flowing in that insulation resistance 58B increases, and the common current I_{R} also increases. Since the increase in the common current I_{R} leads to the increase in the monitor voltage, a prescribed threshold value is set to the monitor voltage, and it is possible to determine that abnormal insulation of the piezoelectric element 58 has occurred when the monitor voltage exceeds the threshold value.

Abnormal insulation caused by a manufacturing defect or abnormal insulation caused by migration occurs in ones among the plurality of piezoelectric elements, and abnormal insulation caused by the exuding of ink to the live parts occurs evenly across the plurality of piezoelectric elements.

The abnormal insulation determination unit 150 of the present embodiment determines the abnormal insulation even if at least one of the piezoelectric elements 58 is subject to abnormal insulation, by simultaneously applying a drive voltage to the piezoelectric elements 58 and determining the status of abnormal insulation of the piezoelectric elements 58.

More specifically, the total current flowing in the insulation resistances is collectively measured, and it is determined that abnormal insulation has occurred in both cases where there is even one piezoelectric element 58 in which the insulation resistance 58B has deteriorated, and where the deterioration of the insulation resistance 58B has evenly occurred partially or entirely in the plurality of piezoelectric elements 58. In order to identify the piezoelectric element 58 with a deteriorated insulation resistance 58B, DC current is applied sequentially to each piezoelectric element 58 to individually check the piezoelectric elements 58.

Moreover, according to the function of the capacitor 162 provided to the common line 116, even if a pulse current flows when the piezoelectric elements 58 are operated, the impedance of the common line 116 against the pulse current is approximately zero, and the monitor voltage appears at both ends of the monitor resistor 156. Hence, even when the piezoelectric elements 58 are being operated, the status of abnormal insulation of the piezoelectric elements 58 can be determined in accordance with the current flowing in the monitor resistor 156.

As described above, in the piezoelectric elements 58, there are cases where the resistance value of the insulation resistance 58B deteriorates in a range where it is not considered abnormal insulation. During the period from the time that the insulation resistance 58B is within a normal range but deteriorated to reaching the abnormal insulation, it is necessary to prevent the damage of the drive circuit 100 caused by the overload (increase of consumption current) of the drive circuit 100 caused by the deterioration in the insulation resistance 58B, and simultaneously continue the determination of the abnormal insulation.

The common current controller 152 shown in FIG. 8 is configured to detect the current flowing in the monitor resistor 156 (i.e., the common current I_{R}), thereby detect the overload status of the monitor resistor 156 and the respective elements (for instance, the transistors 144 and 146 of the amplifier 124) configuring the drive circuit 100, and limit the common current I_{R} to resolve the overload status when the overload status is detected.

Moreover, since the common current controller 152 does not interrupt the common current I_{R}, and rather limits the common current I_{R} to be within a range there the status of abnormal insulation can be determined using the abnormal insulation determination unit 150, the abnormal insulation determination unit 150 is able to determine the abnormal insulation even in a state where the common current I_{R} is limited.

The overload status of the monitor resistor 156 may be set, for instance, to a prescribed value from ½ of the rated power of the monitor resistor 156 to a range that does not exceed the rated power. More specifically, if the rated power of the monitor resistor 156 is 1 W, it is determined as the overload status when the power consumption of the monitor resistor 156 exceeds 0.5 W (½ of the rated power) or 0.75 W (¾ of the rated power). As a result of determining the overload status as described above, the power consumption of the monitor resistor 156 does not exceed the rated power of the monitor resistor 156 even in the worst case scenario.

The criterion of the current for determining the overload status of the monitor resistor 156 can be determined according to the criterion of the power consumption and the resistance value of the monitor resistor 156.

The threshold value to be used by the abnormal insulation determination unit 150 for determining the abnormality is obtained from the ratio of the voltage of the output 124A and the voltage of the common line 116. For example, the threshold value can be set to approximately “voltage of common line 116”/“voltage of output 124A”=0.03 (3%).

### Configuration of Common Current Controller

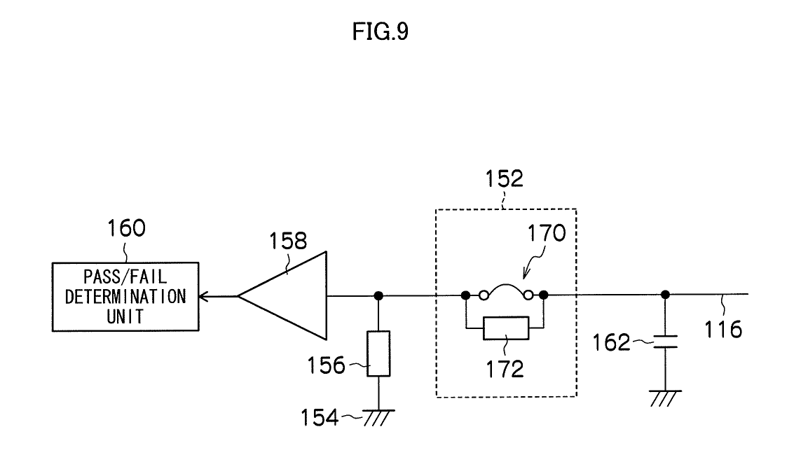

A specific configuration example of the common current controller 152 is described with reference to FIGS. 9 to 11. FIGS. 9 to 11 only illustrate the configuration of the common current controller 152 and its periphery, and the illustration of the overall configuration of the drive circuit 100 is omitted. Moreover, the components in FIGS. 9 to 11 that are the same as or similar to the other drawings are denoted with the same reference numerals, and the explanation thereof is omitted.

FIG. 9 shows a configuration example of the common current controller 152 where a fuse 170 and a resistor 172 having a prescribed resistance value are connected in parallel. In the configuration example shown in FIG. 9, since the resistance value of the fuse 170 is generally sufficiently smaller than the monitor resistor 156 or the parallel-connected resistor 172, the common current I_{R} flows in the fuse 170 in a normal status, and the monitor resistor 156 is able to accurately monitor the insulation resistance 58B of the piezoelectric element 58.

Meanwhile, when the insulation resistance 58B of the piezoelectric element 58 decreases and the common current I_{R} becomes greater than the fusing current of the fuse 170, then the fuse 170 is broken. After the fuse 170 is broken, the common current I_{R} flows in the monitor resistor 156 though the resistor 172. Thus, it is possible to determine the status of abnormal insulation of the piezoelectric elements 58. Moreover, since the resistance value of the resistor 172 is determined to correspond to the limitation range of the common current I_{R}, the common current I_{R} is limited within an appropriate range, and it is thereby possible to avoid any damage in the monitor resistor 156 and the drive circuit 100 caused by an overload.

In the mode shown in FIG. 9, a fuse resistor may be used in substitute for the fuse 170, and a self-resetting current interruption element such as a thermistor may also be used. When using a fuse or a fuse resistor, it is necessary to replace the component once it is disconnected. On the other hand, when a thermistor (positive thermistor) is used, it is not necessary to replace components, and the circuit can be reused after the resetting (cooling).

According to the mode shown in FIG. 9, the limitation of the common current I_{R} can be realized with a simple configuration. Moreover, the number of components is few, and the components that are used are general-purpose components. Thus, it is not necessary to enlarge the drive circuit board 101, and this is also advantageous from the perspective of cost reduction.

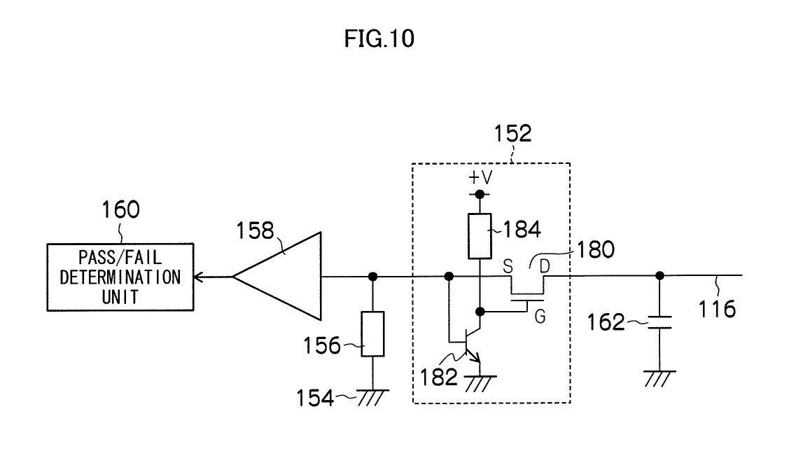

FIG. 10 shows a configuration example using a switching element such as a transistor as the common current controller 152. With the configuration example shown in FIG. 10, a field-effect transistor (FET) 180 is inserted in the common line 116 (between the capacitor 162 and the monitor resistor 156). The drain (D) terminal of the FET 180 is connected to the capacitor 162, and the source (S) terminal is connected to the monitor resistor 156. Moreover, connected to the gate (G) terminal are the collector termination of an NPN transistor 182 and one terminal of the resistor 184, and the other terminal of the resistor 184 is connected to the power source (+V).

The base terminal of the transistor 182 is connected to the S terminal of the FET 180 (and the monitor resistor 156), and the emitter terminal is connected to the ground.

The operation of the common current controller 152 shown in FIG. 10 is briefly explained. When the insulation resistance 58B of the piezoelectric element 58 is in a normal range and the common current I_{R} is in a normal range (prescribed reference value or less), the bias circuit of the transistor 182 is determined so that the transistor 182 is in the OFF state. More specifically, if the monitor voltage as the voltage between both ends of the monitor resistor 156 is less than a prescribed reference value, the transistor 182 is in the OFF state.

Here, the voltage of +V is applied to the G terminal of the FET 180, and the voltage (V_{GS}) between the gate and source is the voltage (approximately +V) obtained by subtracting the monitor voltage from +V, and the FET 180 is thereby the ON state. When the FET 180 is in the ON state, the common current I_{R} flows to the monitor resistor 156 through the D-S of the FET 180.

Meanwhile, when the insulation resistance 58B of the piezoelectric element 58 decreases and the common current I_{R} flowing through the FET 180 increases, the monitor voltage then increases, and the transistor 182 is eventually turned ON. Here, until the transistor 182 is turned ON, the V_{GS} of the FET 180 decreases for the amount that the potential of the S terminal as the monitor voltage rises. More specifically, the V_{GS} decreases approximately 0.7V (voltage between the base and the emitter of the transistor 182) from +V.

The FET 180 needs to have characteristics of being able to maintain the ON state even if the V_{GS} decreases until the transistor 182 is turned ON. When the transistor 182 is turned ON, the potential of the G terminal of the FET 180 becomes a saturation voltage between the collector and the emitter of the transistor 182 (normally approximately 0.2V).

When the transistor 182 is turned ON, the potential of the S terminal of the FET 180 becomes a voltage between the base and the emitter of the transistor 182, which is approximately 0.7V. Therefore, this makes V_{GS}<0 volt, and the FET 180 is turned OFF. When the FET 180 is turned OFF, the common current I_{R} flowing from the D terminal of the FET 180 to the monitor resistor 156 through the S terminal is interrupted.

When the FET 180 is turned OFF, the monitor voltage drops since the common current I_{R} does no longer flow to the monitor resistor 156, and the transistor 182 is turned ON when the monitor voltage drops to a prescribed reference value or lower. When the transistor 182 is turned ON, the drain current (common current I_{R}) from the D terminal of the FET 180 toward the S terminal flows since the FET 180 is turned ON, and the common current I_{R} will also flow in the monitor resistor 156.

When the FET 180 is turned ON, since the monitor voltage increases, the transistor 182 is turned ON once again, and the FET 180 is turned OFF. As a result of repeating the ON/OFF of the FET 180 as described above, an equilibrium status is ultimately achieved. The monitor voltage in this equilibrium status is roughly 0.7V.

Thus, the ON/OFF (ON duty) of the FET 180 is controlled with the transistor 182 according to the monitor voltage, and the drain current (common current I_{R}) from the D terminal to the S terminal of the FET 180 is thereby limited to be within a prescribed range.

According to the mode shown in FIG. 10, in comparison to the cases of using a fuse or a thermistor as shown in FIG. 9, it is possible to hold down the current in which the common current controller 152 begins to function. Although the operation current of a general fuse or thermistor is relatively large; with the configuration shown in FIG. 10, since the common current controller 152 starts its operation when the monitor voltage becomes a voltage (approximately 0.7V) for turning ON the transistor 182, the limitation start current of the common current I_{R} and the limitation range of the common current I_{R} can be freely set by selecting an appropriate resistance value of the monitor resistor 156.

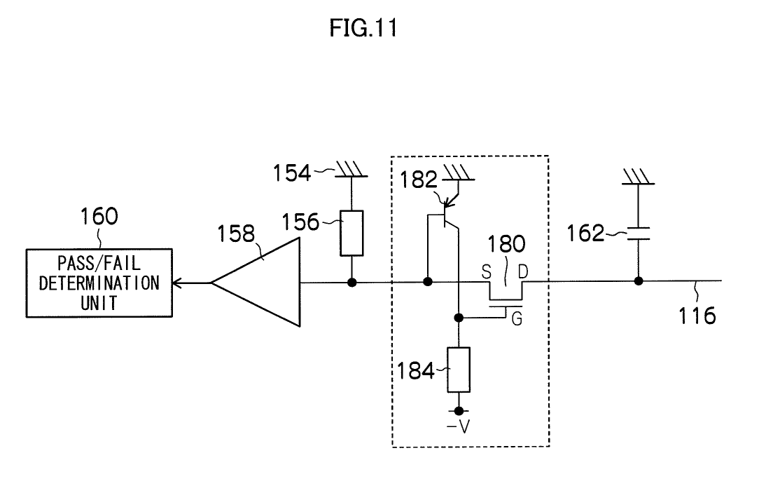

FIG. 11 shows a configuration example of the common current controller 152 in the case where the output voltage of the drive circuit 100 is a minus voltage. In the configuration example shown in FIG. 11, a P-channel FET is applied as the FET 180, and a PNP bipolar transistor is applied as the transistor 182. Moreover, a −V of the negative polarity is applied to the G terminal of the FET 180 through the resistor 184. Since the operating principle is common with the configuration example shown in FIG. 10, the explanation thereof is omitted.

FIG. 8 shows the example of the drive circuit that generates a drive voltage of the positive polarity, and in the piezoelectric element 58, a drive voltage having the positive polarity may be applied to the drive electrode 57 in relation to the common electrode 56, or a drive voltage having the negative polarity may be applied to the drive electrode 57 in relation to the common electrode 56, and the polarity of the drive voltage is determined based on the design of the head.

When applying a drive voltage having the negative polarity to the drive electrode 57 in relation to the common electrode 56 in order to operate the piezoelectric element 58, the configuration example shown in FIG. 11 is applied.

According to the drive circuit configured as described above, since it is possible to detect the current (common current) flowing in the monitor resistor for detecting the abnormal insulation of the piezoelectric elements, it is possible to detect the overload status of the monitor resistor and the drive circuit. In addition, since the current flowing in the monitor resistor is limited if the monitor resistor and the drive circuit are of an overload status, it is possible to prevent the monitor resistor and the drive circuit from becoming overloaded.

Moreover, since the current flowing in the monitor resistor is limited to a range where it is possible to determine the abnormal insulation of the piezoelectric elements, even if the current flowing in the monitor resistor is limited, it is possible to determine the abnormal insulation of the piezoelectric element.

Although the above-descried embodiments concern a drive circuit of an inkjet liquid ejection head as the application example, the present invention can also be applied to a drive circuit for generating a drive signal to be used in driving a piezoelectric actuator such as a piezoelectric element.

In addition, although the inkjet recording apparatus for forming color images on a recording medium has been explained as an example of a device to which the present invention is applied, the present invention can also be broadly applied to various configurations where a piezoelectric actuator is applied as the ejection force generating element such as a liquid ejection apparatus (dispenser or the like) that ejects liquid on a medium from a liquid ejection head.

As apparent from the foregoing detailed description of the embodiments of the present invention, this specification includes the disclosure of various technical concepts including at least the invention indicated below.

A liquid ejection head drive circuit comprises: a drive voltage application device which applies drive voltage between a drive electrode and a common electrode of a piezoelectric element arranged in a liquid ejection head; a detection device which detects a current flowing in a common line which is electrically connected to the common electrode; an abnormal insulation determination device which determines a status of abnormal insulation of the piezoelectric element according to a detection result of the detection device; and a current limitation device which limits the current flowing in the common line within a prescribed range where the abnormal insulation determination device is enabled to determine the status of abnormal insulation, when the current flowing in the common line exceeds a reference value which is determined so that at least one of the detection device and the drive voltage application device is prevented from being overloaded.

According to this aspect of the present invention, when the current flowing in the common line to become a criterion of abnormal insulation of the piezoelectric element exceeds the reference value which is determined so that at least either the detection device or the drive voltage application device is prevented from being overloaded, since the current flowing in the common line is limited, it is possible to avoid damages to the detection device or the drive voltage application device due to an overload. Moreover, since the current flowing in the common line is limited within the range where the status of abnormal insulation of the piezoelectric element can be determined, the status of abnormal insulation of the piezoelectric element can be determined even in a state where the current flowing in the common line is limited.

The drive voltage application device is of a concept of including a low voltage circuit (circuit to handle small signals) which converts waveform data into prescribed analog signals, and a power circuit (circuit to handle high voltage, large current) which converts the analog signals into the current and voltage which are required for driving the piezoelectric actuator.

The expression “abnormal insulation of the piezoelectric element” refers to a status where the piezoelectric element insulation performance has deteriorated, and includes a status where the insulation resistance value of the piezoelectric element has deteriorated.

It is preferable that the current limitation device includes: a current interruption element which interrupts the current flowing in the common line when the current exceeds the reference value; and a resistor which is parallelly connected to the current interruption element.

According to this aspect of the present invention, the common current can be limited according to the prescribed reference value using a simple configuration, and it is thereby possible to prevent the drive circuit from becoming enlarged or complicated.

As the current interruption element, a current fusing element such as a fuse or a thermal fusing element such as a thermistor may be used.

It is preferable that the detection device includes a monitor resistor electrically connected between the common line and a ground.

According to this aspect of the present invention, the monitor voltage, which is proportionate to the current flowing in the common line, appears between both ends of the monitor resistor.

It is preferable that the current limitation device includes: a first switch element which is arranged to the common line; and a current limitation control device which controls the first switch element so as to limit the current flowing in the common line within the prescribed range when a monitor voltage generated between both ends of the monitor resistor exceeds a voltage corresponding to the reference value.

As the first switch element, a bipolar transistor or a field-effect transistor (FET) is preferably used.

It is preferable that the first switch element has a first terminal which is electrically connected to the common electrode and a second terminal which is electrically connected to the monitor resistor; and the current limitation control device includes a second switch element which turns on and off the first switch element according to the monitor voltage generated between both ends of the monitor resistor.

If an FET is applied as the first switch element, the first terminal is a drain terminal, and the second terminal is a source terminal. In addition, the second switch element is connected to a gate terminal.

If a bipolar transistor is applied to the second switch element, the emitter terminal is connected to the ground, and the base terminal is connected to the monitor resistor. In addition, the collector terminal is connected to the bias power source of the first switch element through a resistor.

It is preferable that a capacitor is electrically connected between the common line and a ground.

According to this aspect of the present invention, even if the current flowing in the common line is a pulse current, the impedance of the common line can be lowered. Thus, the detection device is able to detect the common current.

In the foregoing mode, the capacitor is preferably arranged between the common electrode and the current limitation device, and more preferably arranged in close proximity to the current limitation device.

A liquid ejection apparatus includes: a liquid ejection head which ejects liquid; and a liquid ejection head drive circuit which drives the liquid ejection head and has one of the above-described compositions.

A method of protecting a liquid ejection head drive circuit comprises: a drive voltage application step of applying drive voltage between a drive electrode and a common electrode of a piezoelectric element arranged in a liquid ejection head; a detection step of detecting a current flowing in a common line which is electrically connected to the common electrode; an abnormal insulation determination step of determining a status of abnormal insulation of the piezoelectric element according to a detection result in the detection step; and a current limitation step of limiting a current flowing in the common line within a prescribed range where the abnormal insulation determination step is enabled to determine the status of abnormal insulation, when the current flowing in the common line exceeds a reference value which is determined so that overload is prevented in at least one of the detection step and the drive voltage application step.

It should be understood, however, that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A liquid ejection head drive circuit, comprising:
a drive voltage application device which applies drive voltage between a drive electrode and a common electrode of a piezoelectric element arranged in a liquid ejection head;
a detection device which detects a current flowing in a common line which is electrically connected to the common electrode;
an abnormal insulation determination device which determines a status of abnormal insulation of the piezoelectric element according to a detection result of the detection device; and
a current limitation device which limits the current flowing in the common line within a prescribed range where the abnormal insulation determination device is enabled to determine the status of abnormal insulation, when the current flowing in the common line exceeds a reference value which is determined so that at least one of the detection device and the drive voltage application device is prevented from being overloaded.

2. The liquid ejection head drive circuit as defined in claim 1, wherein the current limitation device includes:
a current interruption element which interrupts the current flowing in the common line when the current exceeds the reference value; and
a resistor which is parallelly connected to the current interruption element.

3. The liquid ejection head drive circuit as defined in claim 2, wherein the current interruption element is a fuse.

4. The liquid ejection head drive circuit as defined in claim 2, wherein the current interruption element is a thermistor.

5. The liquid ejection head drive circuit as defined in claim 1, wherein the detection device includes a monitor resistor electrically connected between the common line and a ground.

6. The liquid ejection head drive circuit as defined in claim 5, wherein the current limitation device includes:
a first switch element which is arranged to the common line; and
a current limitation control device which controls the first switch element so as to limit the current flowing in the common line within the prescribed range when a monitor voltage generated between both ends of the monitor resistor exceeds a voltage corresponding to the reference value.

7. The liquid ejection head drive circuit as defined in claim 6, wherein:
the first switch element has a first terminal which is electrically connected to the common electrode and a second terminal which is electrically connected to the monitor resistor; and
the current limitation control device includes a second switch element which turns on and off the first switch element according to the monitor voltage generated between both ends of the monitor resistor.

8. The liquid ejection head drive circuit as defined in claim 7, wherein the first switch element is a field-effect transistor and the second switch element is a bipolar transistor.

9. The liquid ejection head drive circuit as defined in claim 1, wherein a capacitor is electrically connected between the common line and a ground.

10. A liquid ejection apparatus, comprising:
a liquid ejection head which ejects liquid; and
a drive circuit which drives the liquid ejection head, the drive circuit including:
a drive voltage application device which applies drive voltage between a drive electrode and a common electrode of a piezoelectric element arranged in the liquid ejection head;
a detection device which detects a current flowing in a common line which is electrically connected to the common electrode;
an abnormal insulation determination device which determines a status of abnormal insulation of the piezoelectric element according to a detection result of the detection device; and
a current limitation device which limits the current flowing in the common line within a prescribed range where the abnormal insulation determination device is enabled to determine the status of abnormal insulation, when the current flowing in the common line exceeds a reference value which is determined so that at least one of the detection device and the drive voltage application device is prevented from being overloaded.

11. The liquid ejection apparatus as defined in claim 10, wherein the current limitation device includes:
a current interruption element which interrupts the current flowing in the common line when the current exceeds the reference value; and
a resistor which is parallelly connected to the current interruption element.

12. The liquid ejection apparatus as defined in claim 11, wherein the current interruption element is a fuse.

13. The liquid ejection apparatus as defined in claim 11, wherein the current interruption element is a thermistor.

14. The liquid ejection apparatus as defined in claim 10, wherein the detection device includes a monitor resistor electrically connected between the common line and a ground.

15. The liquid ejection apparatus as defined in claim 14, wherein the current limitation device includes:
a first switch element which is arranged to the common line; and
a current limitation control device which controls the first switch element so as to limit the current flowing in the common line within the prescribed range when a monitor voltage generated between both ends of the monitor resistor exceeds a voltage corresponding to the reference value.

16. The liquid ejection apparatus as defined in claim 15, wherein:
the first switch element has a first terminal which is electrically connected to the common electrode and a second terminal which is electrically connected to the monitor resistor; and
the current limitation control device includes a second switch element which turns on and off the first switch element according to the monitor voltage generated between both ends of the monitor resistor.

17. The liquid ejection apparatus as defined in claim 16, wherein the first switch element is a field-effect transistor and the second switch element is a bipolar transistor.

18. The liquid ejection apparatus as defined in claim 10, wherein a capacitor is electrically connected between the common line and a ground.

19. A method of protecting a liquid ejection head drive circuit, comprising:
a drive voltage application step of applying drive voltage between a drive electrode and a common electrode of a piezoelectric element arranged in a liquid ejection head;
a detection step of detecting a current flowing in a common line which is electrically connected to the common electrode;
an abnormal insulation determination step of determining a status of abnormal insulation of the piezoelectric element according to a detection result in the detection step; and
a current limitation step of limiting a current flowing in the common line within a prescribed range where the abnormal insulation determination step is enabled to determine the status of abnormal insulation, when the current flowing in the common line exceeds a reference value which is determined so that overload is prevented in at least one of the detection step and the drive voltage application step.
